(19) United States
(12) Patent Application Publication
(10) Pub. No.: US 2025/0197687 A1
(43) Pub. Date: Jun. 19, 2025

(54) ADHESIVE FILM FOR SEMICONDUCTORS, DICING DIE BONDING FILM, AND METHOD FOR MANUFACTURING SEMICONDUCTOR DEVICE

(71) Applicant: Resonac Corporation, Minato-ku, Tokyo (JP)

(72) Inventors: Yui KUNITO, Minato-ku, Tokyo (JP); Kanami NAKAMURA, Minato-ku, Tokyo (JP); Haemil CHOI, Minato-ku, Tokyo (JP)

(21) Appl. No.: 18/848,914

(22) PCT Filed: Mar. 23, 2023
(86) PCT No.: PCT/JP2023/011426

§ 371 Date: Sep. 20, 2024

(30) Foreign Application Priority Data
Mar. 25, 2022 (WO) PCT/JP2022/014601

(51) Int. Cl. C09J 7/38; C09J 11/04; H01L 21/56; H01L 21/683; H01L 23/00

(52) U.S. Cl. CPC C09J 7/38; C09J 11/04; H01L 21/56; H01L 21/6836; H01L 24/83; H01L 24/85; C09J 2203/326; H01L 2224/83203; H01L 2224/85095; H01L 2924/186

(57) ABSTRACT

An adhesive film for semiconductors, the adhesive film containing a thermosetting component. The adhesive film exhibits a shear viscosity at a frequency of 4.4 Hz of 2000 Pa·s or more at the minimum and 200000 Pa·s at the maximum in a range of 60 to 150° C. The adhesive film may be used for bonding to a substrate while embedding another semiconductor chip. The adhesive film may be used to bond a semiconductor chip to another semiconductor chip while embedding part or the whole of a wire connected to the other semiconductor chip.

### TECHNICAL FIELD

The present disclosure relates to an adhesive film for semiconductors, a dicing die bonding film, and a method for manufacturing a semiconductor device by using these.

### BACKGROUND ART

A stacked MCP (multi-chip package) in which the capacity is increased by semiconductor chips stacked in multiple stages is widely used. Examples of the stacked MCP include a wire-embedded semiconductor package and a chip-embedded semiconductor package. The structure of a semiconductor package in which a wire is embedded in an adhesive film may be referred to as FOW (film over wire). The structure of a semiconductor package in which a semiconductor chip is embedded in an adhesive film may be referred to as FOD (film over die). As an example of a semiconductor package employing FOD, there is a semiconductor package including a controller chip placed in the lowermost stage and an adhesive film in which the controller chip is embedded (see Patent Literature 1).

### CITATION LIST

### Patent Literature

Patent Literature 1: Japanese Unexamined Patent Publication No. 2014-175459
Patent Literature 2: Japanese Patent No. 5736899

### SUMMARY OF INVENTION

### Technical Problem

In the manufacturing of a semiconductor package having a FOD or FOW structure, it is required that a semiconductor chip or a wire be sufficiently embedded in an adhesive film. An adhesive film having reduced viscosity can exhibit good embeddability, but may cause a large amount of bleeding in which the adhesive film protrudes from an end portion of the semiconductor chip. In particular, when the ratio of the volume of the semiconductor chip or the wire to be embedded to the volume of the adhesive film is large, the semiconductor chip or the wire is less likely to be appropriately embedded, and thus the achievement of both suppression of bleeding and sufficient embeddability is likely to be difficult. For example, in the case where a controller chip is embedded in a thin adhesive film, in many cases the ratio of the volume of the controller chip to be embedded to the volume of the adhesive film is relatively large.

An aspect of the present disclosure relates to an adhesive film capable of improving embeddability in FOD or FOW while suppressing bleeding.

### Solution to Problem

An aspect of the present disclosure relates to an adhesive film for semiconductors, the adhesive film containing a thermosetting component. This adhesive film may exhibit a shear viscosity at a frequency of 4.4 Hz of 2000 Pa·s or more at the minimum and 200000 Pa·s or less at the maximum in a range of 60 to 150° C.

Another aspect of the present disclosure relates to a dicing die bonding film including a dicing film and the adhesive film for semiconductors provided on the dicing film.

Still another aspect of the present disclosure relates to a method for manufacturing a semiconductor device, the method including bonding a second semiconductor chip to a substrate on which a first semiconductor chip is mounted using the adhesive film for semiconductors. The first semiconductor chip is embedded in the adhesive film.

Still another aspect of the present disclosure relates to a method for manufacturing a semiconductor device, the method including bonding a second semiconductor chip to a first semiconductor chip using the adhesive film for semiconductors. A wire is connected to the first semiconductor chip, and part or the whole of the wire is embedded in the adhesive film.

The present disclosure includes the following.
[1]

An adhesive film for semiconductors, the adhesive film containing
a thermosetting component, and
exhibiting a shear viscosity at a frequency of 4.4 Hz of 2000 Pa·s or more at the minimum and 200000 Pa·s or less at the maximum in a range of 60 to 150° C.
[2]

The adhesive film for semiconductors according to [1], the adhesive film having a thickness of 50 to 150 μm.
[3]

The adhesive film for semiconductors according to [1] or [2], the adhesive film being used for bonding a semiconductor chip to a substrate while embedding another semiconductor chip.
[3]′

A use of the adhesive film for semiconductors according to [1] or [2] for manufacturing an adhesive film for semiconductors with which a semiconductor chip is bonded to a substrate while another semiconductor chip is embedded.
[4]

The adhesive film for semiconductors according to [1], the adhesive film having a thickness of 25 to 80 μm.
[5]

The adhesive film for semiconductors according to [1] or [4], the adhesive film being used for bonding a semiconductor chip to another semiconductor chip while embedding part or the whole of a wire connected to the other semiconductor chip.
[5]′

A use of the adhesive film for semiconductors according to [1] or [4] for manufacturing a semiconductor device in which a semiconductor chip is bonded to another semiconductor chip while part or the whole of a wire connected to the other semiconductor chip is embedded.
[6]

The adhesive film for semiconductors according to any one of [1] to [5], the adhesive film further containing an elastomer, in which the content of the elastomer is 10 to 60 mass % based on the mass of the adhesive film.
[7]

The adhesive film for semiconductors according to [6], in which the content of the elastomer is 20 to 55 mass % based on the mass of the adhesive film.
[8]

The adhesive film for semiconductors according to any one of [1] to [7], the adhesive film further containing an inorganic filler, in which the content of the inorganic filler is 60 parts by mass or more relative to 100 parts by mass of the thermosetting component.
[9]

The adhesive film for semiconductors according to [8], in which the content of the inorganic filler is 78 to 267 parts by mass relative to 100 parts by mass of the thermosetting component.
[10]

The adhesive film for semiconductors according to any one of [1] to [9], in which the content of the thermosetting component is 15 to 30 mass % based on the mass of the adhesive film.
[11]

A dicing die bonding film comprising:
a dicing film; and
the adhesive film for semiconductors according to any one of [1] to [10] provided on the dicing film.
[12]

A method for manufacturing a semiconductor device, the method including
bonding a second semiconductor chip to a substrate on which a first semiconductor chip is mounted using the adhesive film according to [1] or [2],
in which the first semiconductor chip is embedded in the adhesive film.
[13]

A method for manufacturing a semiconductor device, the method including
bonding a second semiconductor chip to a first semiconductor chip using the adhesive film for semiconductors according to [1] or [4],
in which a wire is connected to the first semiconductor chip, and
part or the whole of the wire is embedded in the adhesive film.
[14]

The method according to [12], in which the first semiconductor chip is a controller chip.
[15]

The method according to [13], in which the first semiconductor chip is a controller chip.

### Advantageous Effects of Invention

Embeddability in FOD or FOW can be improved while bleeding is suppressed.

### BRIEF DESCRIPTION OF DRAWINGS

FIG. 1 is a schematic cross-sectional view showing an example of an adhesive film.

FIG. 2 is a schematic cross-sectional view showing an example of a multilayer sheet having an adhesive film.

FIG. 3 is a schematic cross-sectional view showing an example of a multilayer sheet having an adhesive film.

FIG. 4 is a schematic cross-sectional view showing an example of a semiconductor device.

FIG. 5 is a process diagram showing an example of a method for manufacturing a semiconductor device.

FIG. 6 is a process diagram showing the example of a method for manufacturing a semiconductor device.

FIG. 7 is a process diagram showing the example of a method for manufacturing a semiconductor device.

FIG. 8 is a process diagram showing the example of a method for manufacturing a semiconductor device.

FIG. 9 is a process diagram showing the example of a method for manufacturing a semiconductor device.

FIG. 10 is a schematic cross-sectional view showing another example of a semiconductor device.

FIG. 11 is a schematic cross-sectional view showing another example of a semiconductor device.

### DESCRIPTION OF EMBODIMENTS

The present invention is not limited to the following examples. In the following examples, the components (including steps and the like) are not essential unless otherwise specified. The sizes of the components in the drawings are conceptual, and the relative relationships between the sizes of components are not limited to those shown in the drawings. The numerical values and the ranges thereof given as examples below do not limit the present disclosure, either.

In the present specification, a numerical range specified using “to” indicates a range including the numerical values written before and after “to” as a minimum value and a maximum value, respectively. In numerical ranges written in stages in the present specification, the upper limit value or the lower limit value written in a numerical range may be replaced with the upper limit value or the lower limit value of another numerical range written in stage. In a numerical range written in the present specification, the upper limit value or the lower limit value of the numerical range may be replaced with a value shown in Examples.

In the present specification, a (meth)acrylate means an acrylate or a methacrylate corresponding thereto. The same applies to other similar expressions such as a (meth)acryloyl group and a (meth)acrylic copolymer.

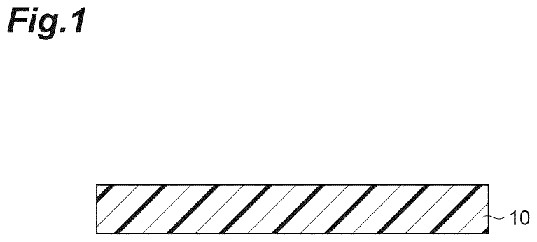

FIG. 1 is a schematic cross-sectional view showing an example of an adhesive film. An adhesive film 10 shown in FIG. 1 can be, for example, a film formed of a thermosetting adhesive containing a thermosetting component, an elastomer, and an inorganic filler. The adhesive film 10 may be in a semi-cured (B-stage) state.

By findings by the present inventors, it is found that the shear viscosity of the adhesive film 10 at, in particular, a frequency of 4.4 Hz in a range of 60 to 150° C. relates to the embeddability and the degree of bleeding of the adhesive film 10. When the shear viscosity of the adhesive film 10 at a frequency of 4.4 Hz is 2000 Pa·s or more at the minimum and 200000 Pa·s or less at the maximum in a range of 60 to 150° C., embeddability in FOD or FOW can be improved while bleeding is suppressed.

From the viewpoint of suppression of bleeding or the like, the minimum value of shear viscosity at a frequency of 4.4 Hz exhibited by the adhesive film 10 at 60 to 150° C. may be 2200 Pa·s or more, 2300 Pa·s or more, or 2400 Pa·s or more. The minimum value of shear viscosity at a frequency of 4.4 Hz exhibited by the adhesive film 10 at 60 to 150° C. may be 10000 Pa·s or less, 9000 Pa·s or less, 8000 Pa·s or less, or 7000 Pa·s or less.

From the viewpoint of further improvement in embeddability, the maximum value of shear viscosity at a frequency of 4.4 Hz exhibited by the adhesive film 10 at 60 to 150° C. may be 180000 Pa·s or less, 175000 Pa·s or less, 170000 Pa·s or less, or 165000 Pa·s or less. The maximum value of shear viscosity at a frequency of 4.4 Hz exhibited by the adhesive film 10 at 60 to 150° C. may be 10000 P·s or more, 11000 Pa·s or more, 12000 Pa·s or more, 13000 Pa·s or more, 14000 Pa·s or more, 15000 Pa·s or more, 16000 Pa·s or more, or 17000 Pa·s or more.

The thickness of the adhesive film 10 may be, for example, 1 μm or more, 3 μm or more, 20 μm or more, 30 μm or more, 35 μm or more, 40 μm or more, 50 μm or more, or 60 μm or more, and may be, for example, 200 μm or less, 150 μm or less, 120 μm or less, 80 μm or less, or 60 μm or less. In the case where the adhesive film 10 is an adhesive film for FOW, the thickness may be, for example, 20 to 120 km, 25 to 80 μm, or 30 to 60 μm in order to embed a wire such that the wire does not come into contact with a semiconductor chip. In the case where the adhesive film 10 is an adhesive film for FOD, the thickness of the adhesive film 10 may be, for example, 40 to 200 μm, 50 to 150 μm, or 80 to 120 μm in order to appropriately embed the whole of a semiconductor chip (for example, a controller chip).

### (a) Thermosetting Component

The thermosetting component contains (a1) a thermosetting resin, which is a compound having a functional group that forms a crosslinked structure by thermosetting reaction. The thermosetting component may further contain (a2) a curing agent that reacts with the thermosetting resin. The thermosetting resin may contain an epoxy resin, which is a compound having an epoxy group, from the viewpoint of adhesiveness. In this case, the curing agent may contain a phenolic resin, which is a compound having a phenolic hydroxy group.

The content of the thermosetting component (the total content of the thermosetting resin and the curing agent) may be 8 mass % or more, 10 mass % or more, or 15 mass % or more, and may be 80 mass % or less, 70 mass % or less, 60 mass % or less, 50 mass % or less, 45 mass % or less, or 30 mass % or less, based on the mass of the adhesive film 10. When the content of the thermosetting component is large, the adhesive force after curing of the adhesive film tends to be improved. When the content of the thermosetting component is 80 mass % or less, securement of film formability when varnish for forming an adhesive film is applied can be expected.

Examples of the epoxy resin include a bisphenol A type epoxy resin, a bisphenol F type epoxy resin, a bisphenol S type epoxy resin, a phenol novolac type epoxy resin, a cresol novolac type epoxy resin, a bisphenol A novolac type epoxy resin, a bisphenol F novolac type epoxy resin, a stilbene type epoxy resin, a triazine skeleton-containing epoxy resin, a fluorene skeleton-containing epoxy resin, a triphenol phenol methane type epoxy resin, a biphenyl type epoxy resin, a xylylene type epoxy resin, a biphenyl aralkyl type epoxy resin, a naphthalene type epoxy resin, and a diglycidyl ether compound derived from a polyfunctional phenol compound or a polycyclic aromatic compound (anthracene or the like). For these, one kind may be used singly, or two or more kinds may be used in combination. From the viewpoint of tackiness, flexibility, etc. of the adhesive film, the epoxy resin may be a cresol novolac type epoxy resin, a bisphenol F type epoxy resin, a bisphenol A type epoxy resin, or a combination thereof.

The thermosetting resin may contain a liquid epoxy resin that is liquid at 25° C. The content of the liquid epoxy resin may be 5 to 15 mass % based on the mass of the adhesive film 10. The thermosetting resin may contain an epoxy resin exhibiting a softening point of less than 30° C. An adhesive film containing these epoxy resins is likely to have good flexibility, and allows the embeddability of a semiconductor chip and a wire with the adhesive film to be improved more. The thermosetting resin may contain an epoxy resin exhibiting a softening point of 50° C. or higher.

Examples of the phenolic resin used as a curing agent include a novolac type phenolic resin, allylated bisphenol A, allylated bisphenol F, allylated naphthalenediol, a phenol aralkyl resin, and a naphthol aralkyl resin. For these, one kind may be used singly, or two or more kinds may be used in combination. The phenolic resin may be a phenol aralkyl resin, a naphthol aralkyl resin, or a combination thereof. The novolac type phenolic resin is obtained by condensation or co-condensation of phenols (for example, phenol, cresol, resorcin, catechol, bisphenol A, bisphenol F, phenylphenol, and aminophenol) and/or naphthols (for example, α-naphthol, β-naphthol, and dihydroxynaphthalene), and a compound having an aldehyde group such as formaldehyde under an acidic catalyst. The phenol aralkyl resin and the naphthol aralkyl resin are synthesized from phenols such as phenol novolac and phenol and/or naphthols, and dimethoxyparaxylene or bis(methoxymethyl)biphenyl.

The hydroxy group equivalent of the phenolic resin may be 70 g/eq or more, or 70 to 300 g/eq. When the hydroxy group equivalent of the phenolic resin is 70 g/eq or more, the storage elastic modulus of the adhesive film tends to be increased more. When the hydroxy group equivalent of the phenolic resin is 300 g/eq or less, foaming and the occurrence of outgassing can be suppressed more.

In the case where the thermosetting resin contains an epoxy resin and the curing agent contains a phenolic resin, the ratio between the epoxy equivalent of the epoxy resin and the hydroxy group equivalent of the phenolic resin (epoxy equivalent:hydroxy group equivalent) may be 0.30/0.70 to 0.70/0.30, 0.35/0.65 to 0.65/0.35, 0.40/0.60 to 0.60/0.40, or 0.45/0.55 to 0.55/0.45 from the viewpoint of curability. When the equivalent ratio is 0.30/0.70 or more, there is a tendency toward more sufficient curability being obtained. When the equivalent ratio is 0.70/0.30 or less, the viscosity can be prevented from being too high, and more sufficient fluidity can be obtained.

The softening point of the curing agent may be 50 to 200° C., or 60 to 150° C. A curing agent having a softening point of 200° C. or lower is likely to have good compatibility with the thermosetting resin.

### (b) Elastomer

The elastomer can be, for example, a polymer compound exhibiting a glass transition temperature (Tg) of 55° C. or lower. Examples of the (b) component include an acrylic resin, a polyester resin, a polyamide resin, a polyimide resin, a silicone resin, a butadiene resin, an acrylonitrile resin, and modified products thereof.

The content of the elastomer may be 10 mass % or more, 11 mass % or more, 12 mass % or more, 13 mass % or more, 14 mass % or more, 15 mass % or more, 16 mass % or more, 17 mass % or more, 18 mass % or more, 19 mass % or more, or 20 mass % or more, and may be 60 mass % or less, 58 mass % or less, 55 mass % or less, or 50 mass % or less, based on the mass of the adhesive film 10. In the case where the adhesive film contains two or more elastomers, the total amount thereof is the content of the elastomer. When the content of the elastomer is 10 mass % or more, the viscosity of the adhesive film is increased, and improvement in handleability of the film and suppression of bleeding can be expected. By the content of the elastomer being 60 mass % or less, embeddability tends to be improved more.

From the viewpoint of fluidity, the elastomer may contain an acrylic resin. Here, the acrylic resin means a polymer containing a monomer unit derived from a (meth)acrylic acid ester. The content of constituent units derived from (meth)acrylic acid ester in the acrylic resin may be, for example, 70 mass % or more, 80 mass % or more, or 90 mass % or more based on the total amount of the acrylic resin. The acrylic resin may contain a monomer unit derived from a (meth)acrylic acid ester having a crosslinkable functional group such as an epoxy group, an alcoholic or phenolic hydroxy group, or a carboxy group. The acrylic resin may be acrylic rubber, which is a copolymer containing a (meth)acrylic acid ester and acrylonitrile as monomer units.

The glass transition temperature (Tg) of the elastomer (for example, an acrylic resin) may be −50° C. or higher, −30° C. or higher, 0° C. or higher, or 3° C. or higher, and may be 50° C. or lower, 45° C. or lower, 40° C. or lower, 35° C. or lower, 30° C. or lower, or 25° C. or lower. When the Tg of the elastomer is low, the adhesive film tends to have good flexibility. An adhesive film having good flexibility is easily cut together with a semiconductor wafer at the time of dicing, and thus can effectively suppress the occurrence of burrs. An adhesive film having good flexibility is easily attached to a semiconductor wafer while voids are sufficiently removed, and furthermore can suppress chipping at the time of dicing due to a reduction in adhesion. The glass transition temperature (Tg) means a value measured using a DSC (thermal differential scanning calorimeter) (for example, “Thermo Plus 2” manufactured by Rigaku Corporation). The Tg of the elastomer can be adjusted to fall within a desired range by adjusting the type and the content of constituent units (in the case of an acrylic resin, constituent units derived from (meth)acrylic acid ester) contained in the elastomer.

The weight-average molecular weight (Mw) of the elastomer (for example, an acrylic resin) may be 100000 or more, 200000 or more, or 300000 or more, and may be 3 million or less, 2 million or less, or 1 million or less. When the Mw of the elastomer is in such a range, film formability, and strength, flexibility, tackiness, etc. in the adhesive film can be appropriately controlled, reflowability is excellent, and embeddability can be improved. Mw means a value converted using a standard polystyrene-based calibration curve measured by gel permeation chromatography (GPC).

Examples of commercially available products of the acrylic resin include SG-70L, SG-708-6, WS-023 EK30, SG-280 EK23, HTR-860P-3CSP, and HTR-860P-3CSP-30B (all manufactured by Nagase ChemteX Corporation), and H-CT-865 (manufactured by Showa Denko Materials Co., Ltd.).

### (c) Inorganic Filler

The inorganic filler may be, for example, particles containing at least one inorganic material selected from aluminum hydroxide, magnesium hydroxide, calcium carbonate, magnesium carbonate, calcium silicate, magnesium silicate, calcium oxide, magnesium oxide, aluminum oxide, aluminum nitride, aluminum borate whisker, boron nitride, and silica. From the viewpoint of adjustment in melt viscosity, the inorganic filler may contain silica.

The average particle size of the inorganic filler may be 0.01 μm or more, or 0.03 μm or more, and may be 1.5 μm or less, 1.0 μm or less, 0.8 μm or less, 0.08 μm or less, or 0.06 μm or less, from the viewpoint of fluidity. Two or more inorganic fillers having different average particle sizes may be combined. Here, the average particle size means a particle size at a cumulative frequency of 50% in a particle size distribution obtained by a laser diffraction/scattering method. The average particle size of the inorganic filler can be determined also by using an adhesive film containing the inorganic filler. In this case, the average particle size of the inorganic filler can be determined from a particle size distribution obtained by a method in which the adhesive film is heated to decompose the resin component, the resulting residue is dispersed in a solvent to prepare a dispersion, and a laser diffraction/scattering method is applied to the dispersion.

The adhesive film may contain (c1) a first inorganic filler and (c2) a second inorganic filler, both satisfying all of the following conditions. By the adhesive film containing the (c1) component and the (c2) component, embeddability can be improved, and furthermore breaking strength can be improved after curing.
The average particle size of the (c1) component be 300 to 1000 nm.
The average particle size of the (c2) component be 0.05 to 0.70 times the average particle size of the (c1) component.
The total content of the (c1) component and the (c2) component be 30 to 60 mass % based on the total amount of the adhesive film.

The average particle size of the (c1) component is 300 to 1000 nm; and may be 350 nm or more, 400 nm or more, or 450 nm or more, and may be 900 nm or less, 800 nm or less, 700 nm or less, or 600 nm or less. The average particle size of the (c2) component may be less than 300 nm, and may be 250 nm or less, 220 nm or less, or 200 nm or less. The average particle size of the (c2) component may be, for example, 10 nm or more, 50 nm or more, or 100 nm or more.

In the present specification, the average particle size regarding each of the (c1) component and the (c2) component means a particle size at a cumulative frequency of 50% in a particle size distribution obtained by a laser diffraction/scattering method. The average particle sizes of the (c1) component and the (c2) component can be determined also by using an adhesive film containing the (c1) component and the (c2) component. In this case, the adhesive film is heated to decompose the resin component, the resulting residue is dispersed in a solvent to prepare a dispersion, and a laser diffraction/scattering method is applied to the dispersion to obtain a particle size distribution; in the particle size distribution, the numerical value of a peak in a range of 300 to 1000 nm can be taken as the average particle size of the (c1) component, and the numerical value of a peak in a range of less than 300 nm can be taken as the average particle size of the (c2) component.

The average particle size of the (c2) component is 0.05 to 0.70 times the average particle size of the (c1) component. The average particle size of the (c2) component may be 0.10 times or more, 0.20 times or more, or 0.30 times or more the average particle size of the (c1) component, and may be 0.60 times or less, 0.50 times or less, or 0.40 times or less the average particle size of the (c1) component.

The content of the (c1) component may be 5 to 40 mass % based on the total amount of the adhesive film; and may be 6 mass % or more, 8 mass % or more, or 10 mass % or more, and may be 35 mass % or less, 32 mass % or less, or 30 mass % or less, based on the total amount of the adhesive film.

The content of the (c2) component may be 10 to 50 mass % based on the total amount of the adhesive film; and may be 15 mass % or more, 18 mass % or more, or 20 mass % or more, and may be 45 mass % or less, 42 mass % or less, or 40 mass % or less, based on the total amount of the adhesive film.

The total content of the (c1) component and the (c2) component is 30 to 60 mass % based on the total amount of the adhesive film; and may be 35 mass % or more, 40 mass % or more, or 45 mass % or more, and may be 55 mass % or less, 52 mass % or less, or 50 mass % or less, based on the total amount of the adhesive film.

The content of the (c1) component may be 10 to 70 mass % based on the total content of the (c1) component and the (c2) component; and may be 15 mass % or more, 18 mass % or more, or 20 mass % or more, and may be 65 mass % or less, 62 mass % or less, or 60 mass % or less, based on the total content of the (c1) component and the (c2) component.

The content of the (c2) component may be 30 to 90 mass % based on the total content of the (c1) component and the (c2) component; and may be 35 mass % or more, 38 mass % or more, or 40 mass % or more, and may be 85 mass % or less, 82 mass % or less, or 80 mass % or less, based on the total content of the (c1) component and the (c2) component.

The content of the inorganic filler may be 60 parts by mass or more, 65 parts by mass or more, 70 parts by mass or more, or 78 parts by mass or more, and may be 300 parts by mass or less, or 267 parts by mass or less, based on the thermosetting component (the total content of the thermosetting resin and the curing agent). When the content of the inorganic filler is large, the shear viscosity at a frequency of 4.4 Hz of the adhesive film 10 tends to be increased. When the content of the inorganic filler is 300 parts by mass or less, an appropriate content of the elastomer is easily secured, and thus film formability and film handleability tend to be improved more.

### (d) Coupling Agent

The adhesive film 10 may further contain a coupling agent. The coupling agent may be a silane coupling agent. Examples of the silane coupling agent include γ-ureidopropyltriethoxysilane, γ-mercaptopropyltrimethoxysilane, 3-(phenylamino)propyltrimethoxysilane, and 3-(2-aminoethyl)aminopropyltrimethoxysilane. For these, one kind may be used singly, or two or more kinds may be used in combination.

### (e) Curing Accelerator

The adhesive film 10 may further contain a curing accelerator that accelerates the curing reaction of the thermosetting component. Examples of the curing accelerator include imidazole and a derivative thereof, an organophosphorus-based compound, a secondary amine, a tertiary amine, and a quaternary ammonium salt. For these, one kind may be used singly, or two or more kinds may be used in combination. From the viewpoint of reactivity, the curing accelerator may be imidazole or a derivative thereof. Examples of derivatives of imidazole include 2-methylimidazole, 1-benzyl-2-methylimidazole, 1-cyanoethyl-2-phenylimidazole, and 1-cyanoethyl-2-methylimidazole. For these, one kind may be used singly, or two or more kinds may be used in combination.

The adhesive film 10 may further contain other components as necessary. Examples of other components include a pigment, an ion scavenger, and an antioxidant.

The adhesive film 10 may be used as, for example, a protective sheet that protects the back surface of a semiconductor element of a flip-chip semiconductor device, or a sealing sheet for sealing the space between the front surface of a semiconductor element of a flip-chip semiconductor device and an adherend.

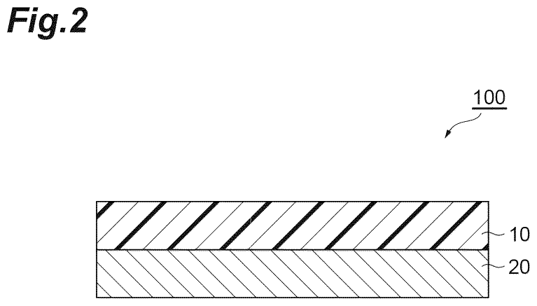

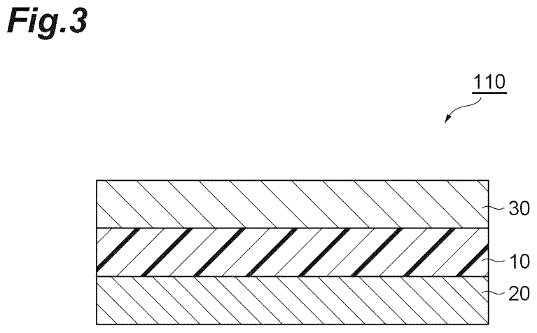

The adhesive film 10 may be supplied in the form of a multilayer sheet shown as an example in FIG. 2 or FIG. 3. A multilayer sheet 100 shown in FIG. 2 includes a base material 20 and an adhesive film 10 provided on the base material 20. A multilayer sheet 110 shown in FIG. 3 further includes a protective film 30 provided on a surface of the adhesive film 10 on the opposite side to the base material 20.

The base material 20 may be a resin film, and examples thereof include a film of polytetrafluoroethylene, polyethylene, polypropylene, polymethylpentene, polyethylene terephthalate, or a polyimide. The thickness of the resin film as the base material 20 may be, for example, 60 to 200 μm, or 70 to 170 μm.

The base material 20 may be a dicing film. The multilayer sheet in which the base material 20 is a dicing film can be used as a dicing die bonding film. The dicing die bonding film may be in a tape form.

Examples of the dicing film include resin films such as a polytetrafluoroethylene film, a polyethylene terephthalate film, a polyethylene film, a polypropylene film, a polymethylpentene film, and a polyimide film. The dicing film may be a resin film surface-treated by primer coating, UV treatment, corona discharge treatment, polishing treatment, or etching treatment as necessary. The dicing film may have stickiness. The dicing film having stickiness may be, for example, a resin film provided with stickiness, or a multilayer body having a resin film and a sticky layer provided on one surface of the resin film. The sticky layer can be formed of a pressure-sensitive or ultraviolet-curable sticking agent. The pressure-sensitive sticking agent is a sticking agent that exhibits certain stickiness by short-time pressurization. The radiation-curable sticking agent is a sticking agent having the property that stickiness is reduced by irradiation with radiation (for example, ultraviolet rays). The thickness of the sticky layer can be set according to the shape and dimensions of the semiconductor device, as appropriate, and may be, for example, 1 to 100 μm, 5 to 70 μm, or 10 to 40 μm. The thickness of the base material 20 that is a dicing film may be 60 to 150 μm or 70 to 130 μm from the viewpoint of economic efficiency and film handleability.

The protective film 30 may be a similar resin film to the base material 20. The thickness of the protective film 30 may be, for example, 15 to 200 μm, or 70 to 170 μm.

### Semiconductor Device and Method for Manufacturing Same

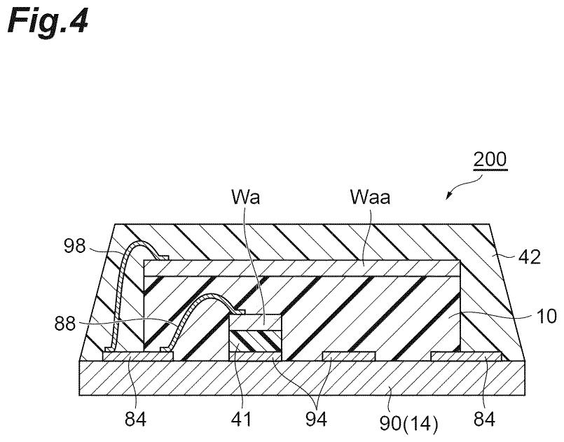

FIG. 4 is a schematic cross-sectional view showing an example of a semiconductor device manufactured using an adhesive film. A semiconductor device 200 mainly includes a substrate 14, a first semiconductor chip Wa and a second semiconductor chip Waa mounted on the substrate 14, a sealing layer 42 that seals the second semiconductor chip Waa, and an adhesive film 10 that bonds the second semiconductor chip Waa to the substrate 14. The substrate 14 includes an organic substrate 90 and circuit patterns 84 and 94 provided on the organic substrate 90. The first semiconductor chip Wa is bonded to the substrate 14 with an adhesive 41. A first wire 88 is connected to the first semiconductor chip Wa, and the first semiconductor chip Wa is electrically connected to the circuit pattern 84 via the first wire 88. The entire first semiconductor chip Wa and the entire first wire 88 are embedded in the adhesive film 10. A second wire 98 is connected to the second semiconductor chip Waa, and the second semiconductor chip Waa is electrically connected to the circuit pattern 84 via the second wire 98. The entire second semiconductor chip Waa and the entire second wire 98 are embedded in the sealing layer 42.

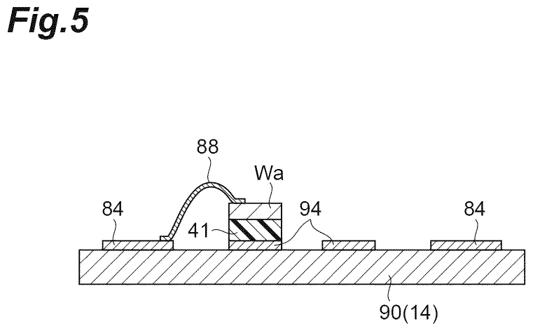

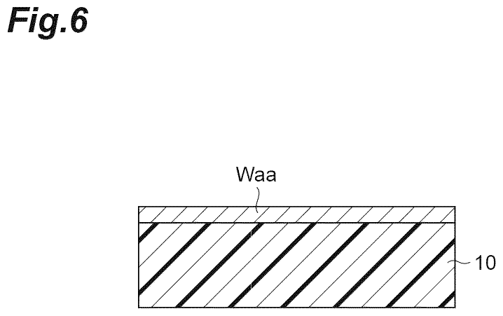

FIGS. 5, 6, 7, 8, and 9 are process diagrams showing an example of a method for manufacturing the semiconductor device 200 of FIG. 4. The method shown in FIG. 5 to 9 includes: bonding a first semiconductor chip Wa to a substrate 14 via an adhesive 41; providing a first wire 88 that connects the first semiconductor chip Wa and the substrate 14 (a circuit pattern 84); preparing an adhesive-attached chip having a second semiconductor chip Wbb and an adhesive film 10 attached thereto; pressure-bonding the adhesive-attached chip to the substrate 14 and thereby bonding the second semiconductor chip Waa to the substrate 14 such that the first semiconductor chip Wa and the first wire 88 are embedded in the adhesive film 10; and providing a second wire 98 that connects the second semiconductor chip Waa and the substrate 14 (the circuit pattern 84). After that, a sealing layer 44 is formed; thereby, the semiconductor device 200 shown in FIG. 4 is obtained.

The thickness of the first semiconductor chip Wa may be 10 to 170 μm. The first semiconductor chip Wa may be a controller chip for driving the semiconductor device 200. The first semiconductor chip Wa may be a flip-chip type chip. The size of the first semiconductor chip Wa is usually equal to or smaller than the size of the second semiconductor chip Waa. The adhesive 41 interposed between the first semiconductor chip Wa and the substrate 14 can be an ordinary adhesive for semiconductors.

The adhesive-attached chip including the second semiconductor chip Waa and the adhesive film 10 can be prepared using, for example, a dicing die bonding film having a similar configuration to the multilayer sheet 100 shown as an example in FIG. 2. In this case, for example, the multilayer sheet 100 (a dicing die bonding film) is attached to one surface of a semiconductor wafer in a direction in which the adhesive film 10 comes into contact with the semiconductor wafer. The surface to which the adhesive film 10 is to be attached may be a circuit surface of the semiconductor wafer, or may be a back surface on the opposite side. The semiconductor wafer to which the multilayer sheet 100 (a dicing die bonding film) is attached is divided by dicing, and thereby fragmented second semiconductor chips Waa are formed. Examples of dicing include blade dicing using a rotary blade, and a method of using a laser to cut the adhesive film 10 together with the semiconductor wafer. After dicing, the sticking force of the dicing film may be reduced by ultraviolet irradiation. The second semiconductor chip Waa is picked up together with the divided adhesive film 10.

The second semiconductor chip Waa may have a size of 20 mm or less in width. The width (or the length of one side) of the second semiconductor chip Waa may be 3 to 15 mm, or 5 to 10 mm.

The semiconductor wafer used for forming the second semiconductor chip Waa may be, for example, a thin semiconductor wafer having a thickness of 10 to 100 μm. The semiconductor wafer may be a wafer of, as well as single crystal silicon, polycrystalline silicon or a compound semiconductor such as any of various ceramics or gallium arsenide. The second semiconductor chip Waa can be one formed of a similar semiconductor wafer.

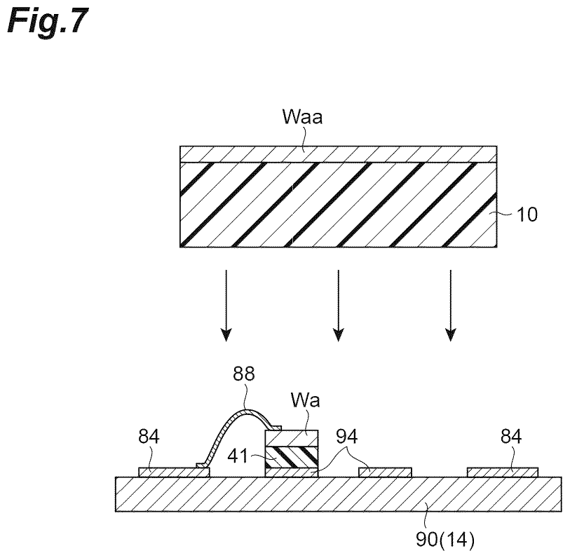

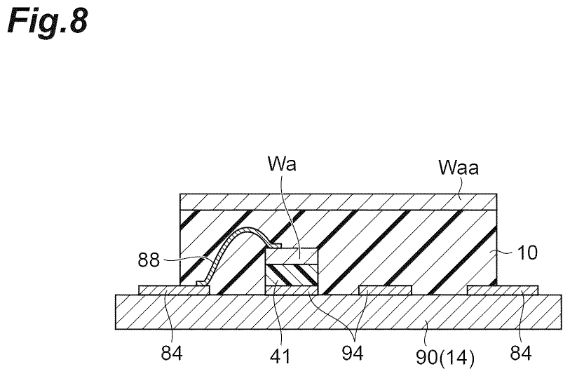

As shown in FIG. 7, the adhesive-attached chip including the adhesive film 10 and the second semiconductor chip Waa is mounted such that the first wire 88 and the first semiconductor chip Wa are covered with the adhesive film 10. Next, as shown in FIG. 8, the second semiconductor chip Waa is pressure-bonded to the substrate 14, and thereby the second semiconductor chip Waa is fixed to the substrate 14. The heating temperature for pressure bonding may be 50 to 200° C., or 100 to 150° C. When the heating temperature for pressure bonding is high, the adhesive film 3 becomes soft, and therefore embeddability tends to be improved more. The pressure bonding period may be 0.5 to 20 seconds, or 1 to 5 seconds. The pressure for pressure bonding may be 0.01 to 5 MPa, or 0.02 to 2 MPa.

After pressure bonding, the structure including the adhesive film 10 may be further heated to cure the adhesive film 10. The temperature and period therefor can be set according to the curing temperature, etc. of the adhesive film 10, as appropriate. The temperature may be changed stepwise. The heating temperature may be, for example, 40 to 300° C., or 60 to 200° C. The heating period may be, for example, 30 to 300 minutes.

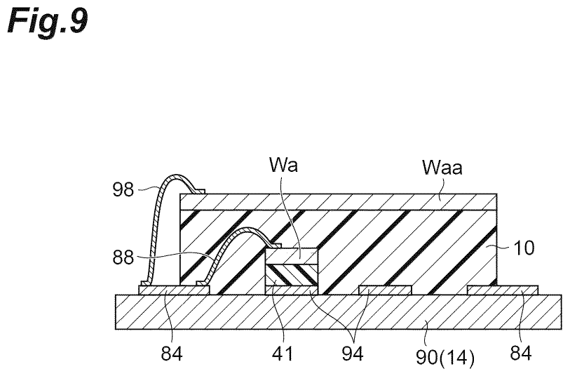

As shown in FIG. 9, the substrate 14 and the second semiconductor chip Waa are electrically connected via the second wire 98. The second wire 98 may be, for example, a gold wire, an aluminum wire, or a copper wire. The heating temperature for connection of the second wire 98 may be in a range of 80 to 250° C., or 80 to 220° C. The heating period for connection of the second wire 98 may be several seconds to several minutes. In order to connect the second wire 98, pressure bonding energy based on vibration energy generated by ultrasonic waves and applied pressure may be applied. The type and the connection method of the first wire 88 can be similar to those of the second wire 98.

After that, a sealing layer 42 that seals the circuit pattern 84, the second wire 98, and the second semiconductor chip Waa is formed by a sealing material. The sealing layer 42 can be formed by, for example, an ordinary method using a mold. After the sealing layer 42 is formed, the adhesive film 10 and the sealing layer 42 may be further thermally cured by heating. The heating temperature therefor may be, for example, 165 to 185° C., and the heating period may be about 0.5 to 8 hours.

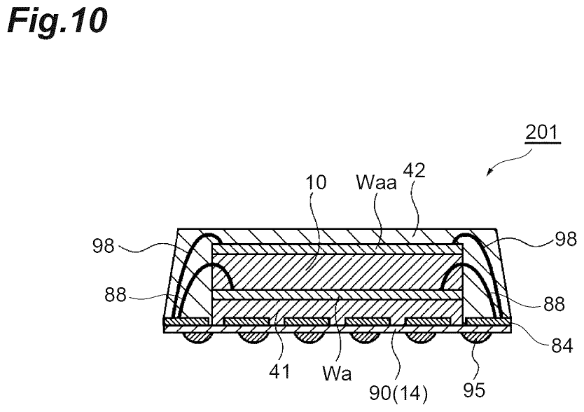

FIG. 10 is a schematic cross-sectional view showing another example of a semiconductor device manufactured using an adhesive film. A semiconductor device 201 shown in FIG. 10 mainly includes a substrate 14, a first semiconductor chip Wa and a second semiconductor chip Waa mounted on the substrate 14, a sealing layer 42 that seals the first semiconductor chip Wa and the second semiconductor chip Waa, and an adhesive film 10 that bonds the second semiconductor chip Waa to the first semiconductor chip Wa. The substrate 14 includes an organic substrate 90, a circuit pattern 84 provided on the organic substrate 90, and connection terminals 95 provided on a surface of the organic substrate 90 on the opposite side to the circuit pattern 84. The first semiconductor chip Wa is bonded to the substrate 14 with an adhesive 41. A first wire 88 is connected to the first semiconductor chip Wa, and the first semiconductor chip Wa is electrically connected to the circuit pattern 84 via the first wire 88. Part of the first wire 88 is embedded in the adhesive film 10. A second wire 98 is connected to the second semiconductor chip Waa, and the second semiconductor chip Waa is electrically connected to the circuit pattern 84 via the second wire 98.

The semiconductor device 201 shown in FIG. 10 can be manufactured by a method similar to the method for manufacturing the semiconductor device 200 including bonding the second semiconductor chip Waa to the first semiconductor chip Wa with the adhesive film 10.

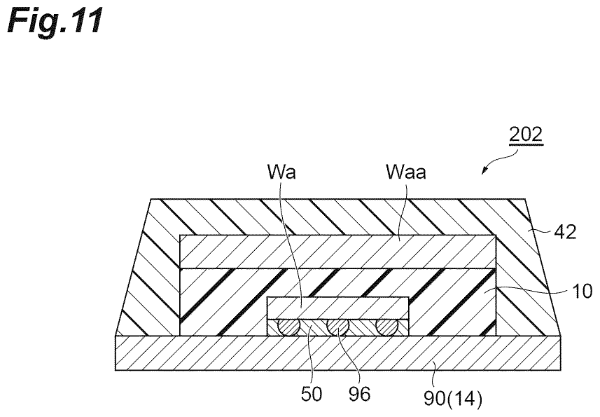

FIG. 11 is a schematic cross-sectional view showing another example of a semiconductor device manufactured using an adhesive film. A semiconductor device 202 shown in FIG. 11 mainly includes a substrate 14 (an organic substrate 90), a first semiconductor chip Wa and a second semiconductor chip Waa mounted on the substrate 14, a sealing layer 42 that seals the first semiconductor chip Wa and the second semiconductor chip Waa, and an adhesive film 10 that bonds the second semiconductor chip Waa to the substrate 14 while embedding the entire first semiconductor chip Wa. The first semiconductor chip Wa is a flip-chip type chip, and is electrically connected to the substrate 14 via a plurality of electrodes 96. An underfill 50 is put between the first semiconductor chip Wa and the substrate 14.

### Examples

### 1. Production of Adhesive Film

### (1) Source Materials

The following source materials were prepared.

### (a1) Thermosetting Resin (Epoxy Resin)

N-500P-10 (trade name, an o-cresol novolac type epoxy resin, manufactured by DIC Corporation, epoxy equivalent: 204 g/eq, softening point: 75 to 85° C.)
EXA-830CRP (trade name, a liquid bisphenol F type epoxy resin, manufactured by DIC Corporation, epoxy equivalent: 159 g/eq)

### (a2) Curing Agent (Phenolic Resin)

MEH-7800M (trade name, a phenyl aralkyl type phenolic resin, manufactured by Meiwa Chemical Co., Ltd., hydroxy group equivalent: 174 g/eq, softening point: 80° C.)
PSM-4326 (trade name, a phenol novolac resin, manufactured by Gun Ei Chemical Industry Co., Ltd., hydroxy group equivalent: 105 g/eq, softening point: 120° C.)
J-DPP-85 (trade name, a dicyclopentadiene type phenolic resin, manufactured by JFE Chemical Corporation, hydroxy group equivalent: 164 to 167 g/eq, softening point: 85 to 89° C.)

### (b) Elastomer (Acrylic Resin)

Acrylic resin A (HTR-860P-3CSP (trade name), manufactured by Nagase ChemteX Corporation, an acrylic resin, weight-average molecular weight: 800000, Tg: 12° C.)
Acrylic resin B (a copolymer of butyl acrylate/ethyl acrylate/ethyl methacrylate/glycidyl methacrylate/styrene, weight-average molecular weight: 400000, Tg: 5° C.)

### (c) Inorganic Filler

Silica filler A (SC 2050-HLG (trade name), a silica filler dispersion, manufactured by Admatechs Co., Ltd., average particle size: 0.50 μm)
Silica filler B (a silica filler dispersion, average particle size: 0.18 μm)

### (d) Curing Accelerator

2PZ-CN (trade name, 1-cyanoethyl-2-phenylimidazole, manufactured by Shikoku Chemicals Corporation)

### (2) Preparation of Adhesive Varnish

An adhesive varnish of an Example or a Comparative Example containing thermosetting resins, a curing agent(s), an elastomer(s), an inorganic filler(s), and a curing accelerator at blending ratios (parts by mass) shown in Table 1, 2, or 3 was prepared. The blending ratio of the inorganic filler shown in the table is the amount of solid content (silica filler). A mixture containing the thermosetting resin, the curing agent, the inorganic filler, and cyclohexanone was stirred. The elastomer was added thereto, and the mixture was stirred. After that, the curing accelerator was added, and the mixture was stirred until the components became uniform; thus, an adhesive varnish of each of Examples 1 to 11 and Comparative Examples 1 to 7 was obtained. Each adhesive varnish was filtered through a 100-mesh filter. Each filtered adhesive varnish was subjected to vacuum defoaming.

### (3) Adhesive Film

A 38 μm-thick polyethylene terephthalate (PET) film subjected to mold release treatment was prepared as a support film. Each adhesive varnish was applied onto the support film. The coating was dried by heating in two stages of 5 minutes at 90° C. and subsequently 5 minutes at 140° C., and an adhesive film (thickness: 60 μm) in a B-stage state was formed on the support film. Two adhesive films obtained were attached together at 70° C., and an adhesive film having a thickness of 120 μm was obtained.

### 2. Evaluation

### (1) Shear Viscosity of Adhesive Film

A plurality of adhesive films were attached together at 80° C., and a multilayer body having a thickness of 1.1±0.1 mm was formed. A measurement sample having a circular surface with a diameter of 9 mm was punched out from the multilayer body. The measurement sample was placed on a circular aluminum plate jig having a diameter of 8 mm. The shear viscosity of the measurement sample was measured under the following conditions using ARES (manufactured by TA Instruments Japan Inc.). From the measurement results, the minimum value and the maximum value of shear viscosity in a range of 60 to 150° C. were read. For some of the adhesive films, also the shear viscosity under the condition of a frequency of 1.0 Hz was measured.

### Measurement Conditions

Measurement temperature: 35 to 160° C.
Rate of temperature increase: 5° C./min
Strain: 5%
Frequency: 4.4 Hz
Initial load: 10 g

The shear viscosity at a frequency of 4.4 Hz of the adhesive film of Example 1 was 7900 Pa·s at 80° C. and 3500 Pa·s at 129° C. (minimum value). The shear viscosity at a frequency of 4.4 Hz of the adhesive film of Example 2 was 6500 Pa·s at 80° C. and 2500 Pa·s at 130° C. (minimum value). The measurement values of shear viscosity of other adhesive films are shown in Table 1.

### (2) Bleeding and Embeddability

### Production of Semiconductor Device for Evaluation

A dicing die bonding film including an adhesive layer and a sticking agent layer (HR-5104-10, the thickness of the adhesive layer: 10 μm, the thickness of the sticky layer: 110 μm, manufactured by Showa Denko Materials Co., Ltd.) was prepared, and this was attached to a semiconductor wafer (diameter: 8 inches, thickness: 40 μm). The semiconductor wafer attached to the dicing die bonding film was cut by dicing using a full auto dicer DFD-6361 (manufactured by DISCO Corporation), and a chip having a size of 1.6 mm×4.1 mm (a first semiconductor chip) was formed. The adhesive-attached chip including the first semiconductor chip and the adhesive layer attached thereto was picked up, and the first semiconductor chip was pressure-bonded to an organic substrate via the adhesive layer by a pressure-bonding machine (a die bonder manufactured by Besi, trade name: Esec 2100sD PPPplus). The conditions of pressure bonding were a temperature of 120° C., a pressure of 0.1 MPa, and a pressure bonding period of 1.5 seconds.

Each adhesive film (thickness: 120 μm) of an Example or a Comparative Example was attached to a sticky film for dicing, and a dicing die bonding film was produced. This dicing die bonding film was attached to a semiconductor wafer (diameter: 8 inches, thickness: 90 μm) in a direction in which the adhesive film came into contact with the semiconductor wafer. The semiconductor wafer attached to the dicing die bonding film was cut by similar dicing to the above, and a second semiconductor chip having a size of 6.0 mm×12.0 mm was formed. The second semiconductor chip and the adhesive film attached thereto were picked up, and the second semiconductor chip was pressure-bonded to the organic substrate under the conditions of a temperature of 120° C., a pressure of 0.1 MPa, and a pressure bonding period of 1.5 seconds such that the entire first semiconductor chip was covered with the adhesive film. The position of the second semiconductor chip was adjusted so that the center positions of the first semiconductor chip and the second semiconductor chip coincided in a planar view. The formed multilayer body was heated under the conditions of a rate of temperature increase of 15° C. Imin, 130° C., and 1 hour to cure the adhesive film, and thereby a semiconductor device for evaluation in which the first semiconductor chip was embedded in the adhesive film was obtained.

### Evaluation of Amount of Bleeding

The upper surface of the second semiconductor chip of the semiconductor device for evaluation was observed using a microscope (manufactured by Keyence Corporation, trade name: VHX-5000). With an end portion of the second semiconductor chip as a starting point, the maximum width (μm) of the adhesive film protruding from the end portion was measured. The amount of bleeding was evaluated according to the following criteria based on the obtained values.
A: Less than 100 μm
B: 100 μm or more

### Embeddability

The interface between the cured adhesive film and the first semiconductor chip in the semiconductor device for evaluation was observed using an ultrasonic digital image diagnostic apparatus (manufactured by Insight k.k., trade name: IS-350) at 75 MHz in a reflection mode, and the area ratio of voids in a predetermined interface was determined. Evaluation was performed according to the following criteria based on the area ratio.
A: The area ratio of voids in a predetermined cross section is less than 5%.
B: The area ratio of voids in the predetermined cross section is 5% or more.

TABLE 1

| | | Ex. 1 | Ex. 2 | Ex. 3 | Ex. 4 | Ex. 5 | Ex. 6 |
|---|---|---|---|---|---|---|---|
| (a1) | N-500P-10 | 7 | 7 | 7 | 5 | 5 | 5 |
| Epoxy | EXA- | 6 | 6 | 6 | 5 | 5 | 5 |
| resin | 830CRP | | | | | | |
| | EXA-4816 | | | | | | |
| | YX8800 | | | | | | |
| (a2) | MEH-7800M | 13 | 13 | 13 | 15 | 15 | 15 |
| Curing | PSM-4326 | 1 | 1 | 1 | 5 | 1 | |
| agent | J-DPP-85 | | | | | | |
| (b) | Acrylic resin | 20 | 10 | 38 | 10 | 44 | 30 |
| Elastomer | A | | | | | | |
| | Acrylic resin | 11 | 11 | 11 | 10 | 10 | 25 |
| | B | | | | | | |
| (c) | Silica filler A | 20 | 10 | 38 | 10 | 10 | 10 |
| Inorganic | | | | | | | |
| filler | Silica filler B | 28 | 38 | 10 | 40 | 10 | 10 |
| Curing | 2PZ-CN | 0.06 | 0.06 | 0.06 | 0.06 | 0.06 | 0.06 |
| accelerator | | | | | | | |
| (a1) + (a2)/total [mass %] | | 26 | 29 | 22 | 30 | 26 | 25 |
| (b)/total [mass %] | | 29 | 21 | 39 | 20 | 54 | 55 |
| (c)/((a1) + (a2)) | | 175 | 175 | 175 | 167 | 78 | 80 |
| [parts by mass] | | | | | | | |
| Shear | Minimum | 3500 | 2500 | 5300 | 6500 | 5000 | 3300 |
| viscosity | value | | | | | | |
| 4.4 Hz | Maximum | 18300 | 17500 | 26400 | 32500 | 19100 | 18000 |
| 60-150° C. | value | | | | | | |
| Shear | Minimum | | 8400 | | | 20500 | |
| viscosity | value | | | | | | |
| 1.0 Hz | Maximum | | 37700 | | | 55000 | |
| 60-150° C. | value | | | | | | |

| | | | | | | |
|---|---|---|---|---|---|---|
| Bleeding | A | A | A | A | A | A |
| Embeddability | A | A | A | A | A | A |

TABLE 2

| | | | | Comp. | Comp. | Comp. | Comp. |
|---|---|---|---|---|---|---|---|
| | | Ex. 7 | Ex. 8 | Ex. 1 | Ex. 2 | Ex. 3 | Ex. 4 |
| (a1) | N-500P-10 | 5 | 5 | 12 | 12 | 9 | 10 |
| Epoxy resin | EXA- | 5 | 5 | 17 | 11 | 12 | 13 |
| | 830CRP | | | | | | |
| | EXA-4816 | | | | | | |
| | YX8800 | | | | | | |
| (a2) | MEH- | 5 | 5 | | | | 19 |
| Curing agent | 7800M | | | | | | |
| | PSM-4326 | | 15 | 13 | 13 | 6 | |
| | J-DPP-85 | | | | | 6 | |
| (b) | Acrylic | 25 | 10 | 14 | 18 | | 18 |
| Elastomer | resin A | | | | | | |
| | Acrylic | 20 | 10 | 5 | 6 | 17 | |
| | resin B | | | | | | |
| (c) | Silica filler | 30 | 40 | 39 | 39 | 50 | 40 |
| Inorganic | A | | | | | | |
| filler | Silica filler | 10 | 10 | | | | |
| | B | | | | | | |
| Curing | 2PZ-CN | 0.06 | 0.06 | 0.06 | 0.06 | 0.06 | 0.06 |
| accelerator | | | | | | | |
| (a1) + (a2)/total [mass %] | | 15 | 30 | 43 | 37 | 33 | 42 |
| (b)/total [mass %] | | 45 | 20 | 18 | 24 | 17 | 18 |
| (c)/((a1) + (a2)) | | 267 | 167 | 92 | 106 | 150 | 95 |
| [parts by mass] | | | | | | | |
| Shear | Minimum | 6300 | 3600 | 400 | 500 | 500 | 700 |
| viscosity 4.4 | value | | | | | | |
| Hz | Maximum | 34400 | 42000 | 7000 | 21400 | 8800 | 12000 |
| 60-150° C. | value | | | | | | |
| Shear | Minimum | | 12100 | | 5700 | | |
| viscosity 1.0 | value | | | | | | |
| Hz | Maximum | | 68200 | | 54000 | | |
| 60-150° C. | value | | | | | | |

| | | | | | | |
|---|---|---|---|---|---|---|
| Bleeding | A | A | B | B | B | B |
| Embeddability | A | A | A | A | A | A |

TABLE 3

| | | | | | Comp. | Comp. |
|---|---|---|---|---|---|---|
| | | Ex. 9 | Ex. 10 | Ex. 11 | Ex. 6 | Ex. 7 |
| (a1) | N-500P- | 11 | 11 | 11 | 10 | 15 |
| Epoxy resin | 10 | | | | | |
| | EXA- | 7 | | | 17 | 14 |
| | 830CRP | | | | | |
| | EXA- | | 7 | | | |
| | 4816 | | | | | |
| | YX8800 | | | 7 | | |
| (a2) | MEH- | 7 | 7 | 7 | | 24 |
| Curing agent | 7800M | | | | | |
| | PSM- | 5 | 5 | 5 | 12 | |
| | 4326 | | | | | |
| | J-DPP-85 | | | | | |
| (b) | Acrylic | 11 | 11 | 11 | 22 | 17 |
| Elastomer | resin A | | | | | |
| | Acrylic | 11 | 11 | 11 | | |
| | resin B | | | | | |
| (c) | Silica | 13 | 13 | 13 | 39 | 29 |
| Inorganic | filler A | | | | | |
| filler | Silica | 36 | 36 | 36 | | |
| | filler B | | | | | |
| Curing | 2PZ-CN | 0.06 | 0.06 | 0.06 | 0.06 | 0.06 |
| accelerator | | | | | | |
| (a1) + (a2)/total [mass %] | | 30 | 30 | 30 | 39 | 54 |
| (b)/total [mass %] | | 21 | 21 | 21 | 22 | 17 |
| (c)/((a1) + (a2)) | | 163 | 163 | 163 | 99 | 55 |
| [parts by mass] | | | | | | |
| Shear | Minimum | 4100 | 3500 | 3900 | 2300 | 200 |
| viscosity 4.4 | value | | | | | |
| Hz | Maximum | 32700 | 21700 | 29600 | 271200 | 161700 |
| 60-150° C. | value | | | | | |

| | | | | | |
|---|---|---|---|---|---|
| Bleeding | A | A | A | A | B |
| Embeddability | A | A | A | B | A |

As shown in Tables 1 to 3, it has been found that, by using an adhesive film of which the shear viscosity at a frequency of 4.4 Hz at 60 to 150° C. is 2000 Pa·s or more at the minimum and 200000 Pa·s or less at the maximum, the lower semiconductor chip can be sufficiently embedded in the adhesive film while the amount of bleeding is suppressed.

### REFERENCE SIGNS LIST

10 adhesive film
14 substrate
20 base material (dicing film)
30 protective film
41 adhesive
42 sealing layer
84, 94 circuit pattern
88 first wire
90 organic substrate
98 second wire
100, 110 multilayer sheet
200, 201, 202 semiconductor device
Wa first semiconductor chip
Waa second semiconductor chip

1. An adhesive film for semiconductors, the adhesive film comprising
a thermosetting component, and
exhibiting a shear viscosity at a frequency of 4.4 Hz of 2000 Pa·s or more at a minimum and 200000 Pa·s or less at a maximum in a range of 60 to 150° C.

2. The adhesive film for semiconductors according to claim 1, the adhesive film having a thickness of 50 to 150 μm.

3. (canceled)

4. The adhesive film for semiconductors according to claim 1, the adhesive film having a thickness of 25 to 80 μm.

5. (canceled)

6. The adhesive film for semiconductors according to claim 1, the adhesive film further comprising an elastomer, wherein a content of the elastomer is 10 to 60 mass % based on a mass of the adhesive film.

7. The adhesive film for semiconductors according to claim 6, wherein the content of the elastomer is 20 to 55 mass % based on the mass of the adhesive film.

8. The adhesive film for semiconductors according to claim 1, the adhesive film further comprising an inorganic filler, wherein a content of the inorganic filler is 60 parts by mass or more relative to 100 parts by mass of the thermosetting component.

9. The adhesive film for semiconductors according to claim 8, wherein the content of the inorganic filler is 78 to 267 parts by mass relative to 100 parts by mass of the thermosetting component.

10. The adhesive film for semiconductors according to claim 1, wherein a content of the thermosetting component is 15 to 30 mass % based on a mass of the adhesive film.

11. A dicing die bonding film comprising:
a dicing film; and
the adhesive film for semiconductors according to claim 1 provided on the dicing film.

12. A method for manufacturing a semiconductor device, the method comprising
bonding a second semiconductor chip to a substrate on which a first semiconductor chip is mounted using the adhesive film according to claim 1,
wherein the first semiconductor chip is embedded in the adhesive film.

13. A method for manufacturing a semiconductor device, the method comprising
bonding a second semiconductor chip to a first semiconductor chip using the adhesive film for semiconductors according to claim 1,
wherein a wire is connected to the first semiconductor chip, and
part or a whole of the wire is embedded in the adhesive film.

14. The method according to claim 12, wherein the first semiconductor chip is a controller chip.

15. The method according to claim 13, wherein the first semiconductor chip is a controller chip.
